(19) United States
(12) Patent Application Publication
(10) Pub. No.: US 2009/0166877 A1
(43) Pub. Date: Jul. 2, 2009

(54) ELECTRO-OPTIC DEVICE AND A METHOD FOR PRODUCING THE SAME

(75) Inventors: Herbert Lifka, Eindhoven (NL); Edward Willem Albert Young, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/296,981

(22) PCT Filed: Apr. 10, 2007
(86) PCT No.: PCT/IB07/51266

§ 371 Date: Oct. 13, 2008

(30) Foreign Application Priority Data
Apr. 18, 2006 (EP) 06112683.5

(51) Int. Cl. H01L 23/48; H01L 21/02; H05K 1/11

(52) U.S. Cl. 257/773; 438/666; 174/261; 257/E23.01; 257/E21.002

(57) ABSTRACT

The present invention relates to a planar electro-optic device and a method for producing the same. The device comprises an embedded woven structure of conductive wires (3), which adjoin the top surface of the substrate (7) at locations thereof. Different electrode layers may be connected to the wires at these locations. The wires may then be used e.g. to provide a uniform potential over an entire electrode surface, even if the electrode itself is very thin. A substrate of this kind may also be used for addressing purposes.

### FIELD OF THE INVENTION

The present invention relates to an electro-optic device, having a planar substrate and at least one electrode layer and an active layer on a first surface of the substrate. The invention further relates to a method for producing such a device, and to a substrate.

### BACKGROUND OF THE INVENTION

A device of the above mentioned kind has been disclosed e.g. by C. W. Tang and S. A. Van Slyke in Appl. Phys. Lett. 51 (1987) 913-915. That device is an OLED (Organic Light Emitting Diode) device for lighting purposes, having an active organic light emitting layer sandwiched between a transparent anode, placed on a transparent substrate, and a cathode. When a voltage is applied between the anode and the cathode, the organic layer emits light, through the anode and the substrate.

One problem with such a device is that, when the active surface becomes larger, a voltage drop occurs over the electrode surfaces. This is due to the fact that the electrode layers are very thin. This means, for the above case with the OLED device, that the current density, and consequently the light emission, will not be uniform over the device surface.

An obvious way to cure this problem would of course be to provide thicker electrode layers. This is however not always useful solution. Firstly, thicker electrode layers reduce light transmission. This is particularly relevant for so-called top emission OLEDs, where the light is propagated through an extremely thin metal cathode layer, but also for e.g. transparent ITO (Indium Tin Oxide) anode layers.

Secondly, depositing thicker layers with evaporation techniques means longer cycle times in expensive machines and hence more expensive products.

### SUMMARY OF THE INVENTION

An object of the present invention is therefore to provide an organic diode device of the initially mentioned kind where an electrode layer may be thin and still provide a uniform voltage over its surface.

This object is achieved with a device according to claim 1, which may be produced with a method as claimed in claim 14. The object may further be achieved using a substrate as defined in claim 16.

More specifically, the invention then relates to an electro-optic device, having a planar substrate, and at least one electrode layer and an active layer, on a first surface of the substrate. The substrate comprises a plurality of conductive wires, which are embedded in the substrate and are arranged in a structure, such that the wires meander to and from said first substrate surface, and adjoins this surface at a number of locations thereof, and said at least one electrode layer is connected to a plurality of said wires at a plurality of said locations.

In such an electro-optic device, the wires in the woven structure may be used to equalize the potential over the entire surface of a very thin electrode layer by providing shunt connections.

Moreover, it is also possible to provide different voltages to different parts of an electrode layer or different electrode layers, by providing different voltages to different wires.

The wires may be arranged in a woven structure which inherently makes the wires meander in suitable way, and the wires, crossing each other in the woven structure, may be electrically insulated from each other.

A first set of wires, running in a first direction in the woven structure, may be connected to a first electrode layer, and a second set of wires, running in a second direction in the woven structure, may be connected to a second electrode layer through apertures in the first electrode layer. Then, wires in at least one of the first or second set of wires may be interconnected to remain on the same electrical potential.

Sub-sets of wires in at least one of the first or second set of wires may be arranged to be controlled separately.

This allows, in e.g. an OLED device, the application of different voltages to different parts of an electrode layer.

At least one of the first or second electrode layers may be divided into mutually insulated sub-sections and different sub-sections may be connected to different wires in the structure. This allows the possibility to provide individually addressable pixels in the device, which is useful if the device is a display or an image sensor.

The substrate may further be flexible.

The device may be realized as a lighting device, e.g. an OLED device, a solar cell, an OLED display, a TFT display or an image sensor.

The invention also relates to a method for producing an electro-optic device of the above indicated kind, the method comprising

arranging a plurality of conductive wires in a structure, on a planar base substrate part,

forming a top substrate layer on top of the base substrate part, such that the structure is embedded in a substrate formed by the base substrate part and the top substrate part,

removing an upper portion of the top substrate layer, such that parts of the conductive wires in the woven structure become exposed at locations in the substrate surface, and

applying at least one electrode layer and an active layer on the substrate, such that said at least one electrode layer is connected to a plurality of said wires at a plurality of said locations.

Further, a planar substrate for electro-optical devices may be achieved, the substrate comprising a plurality of conductive wires, which may be arranged in a woven structure. The wires are embedded in the substrate and are arranged such that they meander to and from a first substrate surface, and adjoins this surface at a number of locations thereof. This substrate offer the possibility of the above mentioned advantages.

These and other aspects of the invention will be apparent from and elucidated with reference to the embodiments described hereinafter.

### BRIEF DESCRIPTION OF THE DRAWINGS

FIG. 1a and 1b illustrate the embedding of a woven wire structure in a substrate. FIGS. 1c and 1d illustrate how the woven structure becomes partially exposed at a surface of the substrate.

FIG. 2 illustrates a cross section along the line I-I in FIG. 1d.

FIGS. 3 and 4 illustrate different alternative embodiments in a view similar to the view in FIG. 2.

FIG. 5a illustrates a substrate with an applied anode layer.

FIG. 5b illustrates an alternative way to apply an anode layer.

FIG. 6 shows a cross-section through the substrate in FIG. 5a.

FIG. 7 illustrates the device in FIG. 6 with an applied organic layer.

FIG. 8 shows the device in FIG. 7 with an applied cathode layer.

FIG. 9 illustrates how a substrate according to an embodiment of the invention can be used in a TFT LCD device.

### DESCRIPTION OF PREFERRED EMBODIMENTS

A description will first be given of how a woven wire structure may be embedded in a glass or plastic substrate. Then descriptions will be given of how substrates of this type may be used in planar electro-optic devices, such as OLEDs (Organic Light Emitting Diodes) and LCDs (Liquid Crystal Displays).

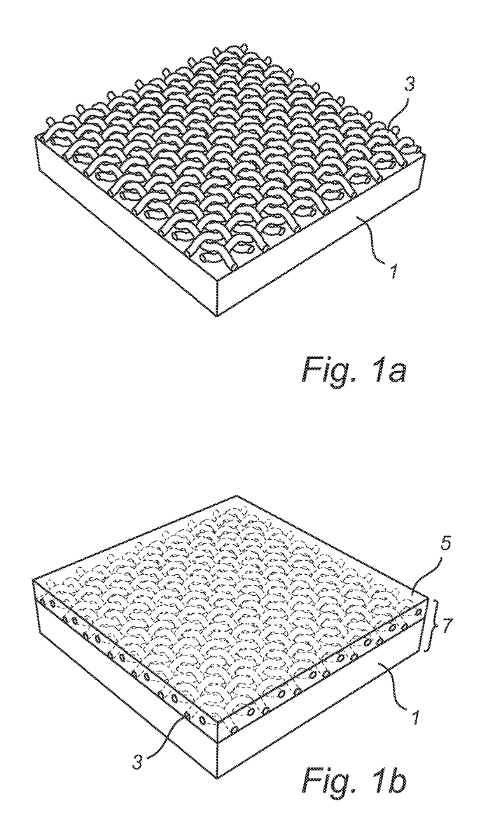

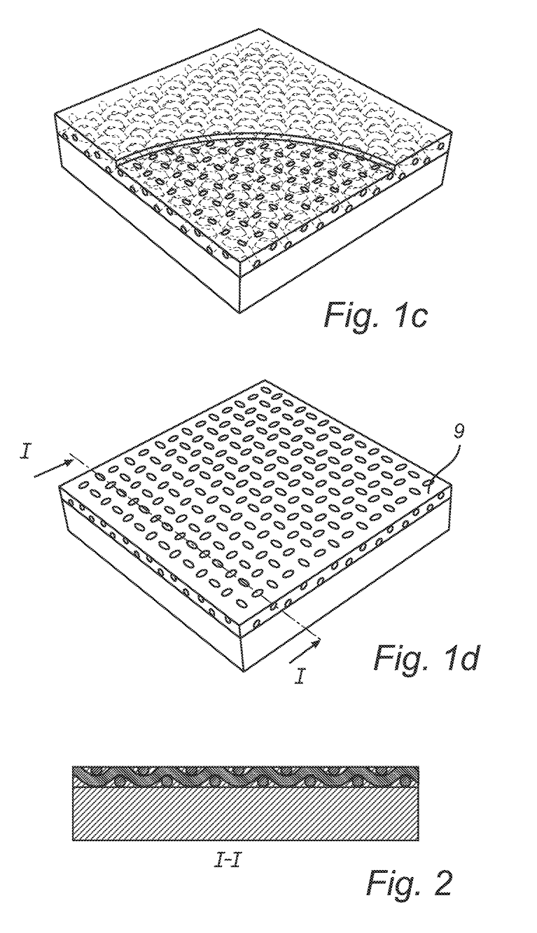

FIGS. 1a and 1b illustrate the embedding of a woven wire structure in a substrate. In FIG. 1a a planar substrate base part 1 is shown which may be made of glass (e.g. soda lime glass or borosilicate glass) or plastic (e.g. polyimide or polycarbonate). The base part 1 may be e.g. 0.6 mm thick. If a flexible plastic substrate is desired the thickness may be e.g. 0.1 mm.

On a top surface of the bottom part, a woven structure consisting of thin wires 3 is placed. The wires may be e.g. 25 μm in diameter and may be of the type often used to wind transformers.

By a woven structure is here meant any generally flat wire assembly accomplished by weaving. In the art of producing fabrics, many useful weaving techniques are know. In addition to the simple warp and weft structure illustrated in FIG. 1a, other bi-axial, tri-axial, etc. structures may be considered. By the use of a woven structure, the individual wires 3 will meander to and from the top surface of the base part in an organized manner.

The thickness of the wires, in relation to the distance between two adjacent parallel wires, is exaggerated in FIG. 1 a in order to make the description more clear. Typically the distance between two adjacent wires may be e.g. 10 mm, while the wires are only 25 μm thick. Thus, the woven structure will not obstruct light passing through the base part in a normal direction to any greater extent. As will be discussed later, both wires with and without insulation may be used.

As alternatives to a woven structure, in which the wires will inherently meander, there are of course other possible structures that will exhibit similar properties. E.g. the substrate base part may provided with grooves and wires may be placed on the base part perpendicularly to the grooves. If the wires are then pressed into the grooves and are deformed, they will be arranged in a structure where they meander to and from the plane of the base part.

In order to embed the woven structure of FIG. 1a in the substrate, a substrate top part 5 is then created on top of the substrate base part 1 as illustrated in FIG. 1b. If the base part is made of glass, a glass paste may then be applied on top of the woven structure and may be partially pressed through the woven structure. A layer of paste, thick enough to completely cover the woven structure is applied. As an alternative to a glass paste, a polymer mixture may be applied. Such a mixture would be applicable both on top of glass and plastic base parts.

The glass paste may be composed of glass particles and a solvent, and by heating the substrate to e.g. 400° C. the solvent will be removed and a solid layer will be formed by the remaining substance of the paste. The woven structure may thus be completely embedded in the substrate as illustrated in FIG. 1b. Note that the top surface of the substrate in this state may be coarse, and not as flat as illustrated in FIG. 1b.

The substrate 7 now comprises a base part 1 and a top part 5, and the woven structure consisting of the wires is embedded in the top part 5. FIG. 1c illustrates how an upper portion of the substrate is removed by polishing to partially expose the conductors in the woven structure, thus forming wire contact surfaces as illustrated. The polishing may be accomplished with different techniques, e.g. silicone polishing. There are further different ways to ensure that the substrate is polished to the right level, i.e. such that the embedded conductors are partially exposed and adjoins the substrate top surface. In an optical method, the substrate surface is scanned with a camera, and it is detected when a desired conductor pattern becomes visible at the surface. It is also possible to detect that the right level is attained by measuring the wire resistance, which begins to increase when the polishing reaches the conductors. It is also possible to determine the polishing depth by measuring the friction on the polishing head of the polishing device. The embedding and polishing is further a reasonably reproducible process, such that polishing time may be used as a means for determining the polishing depth.

When the polishing is completed, the finished substrate has the appearance illustrated in FIG. 1d. The conductive wires, which as mentioned meander to and from the top substrate surface, adjoins this surface at a number of locations thereof, such that a conductive part of the wire becomes accessible as a wire contact area in the surface. This substrate may be used in a number of different planar electro-optic devices, as will be described further. Note that other ways of removing the upper portion of the substrate than polishing are possible, e.g. plasma etching.

Outside the substrate, the wires may be connected to each other or to different voltage sources, depending on the application. It is also possible to use the embedded wires only to interconnect different parts of an electrode or different electrodes.

In some devices, the woven structure should be used to shunt only one single and continuous electrode layer. In such cases all wires 3 in the woven structure can be interconnected and may have the same potential. Thus, there is no reason to keep the wires insulated from each other at locations where they cross. The wires may thus contact each other as shown in FIG. 2 which illustrates a cross section along the line I-I in FIG. 1d. This structure may be accomplished with simple, uninsulated wires.

However, as will be exemplified later, in other circumstances the wires should be insulated from each other. This may be accomplished in different ways.

FIG. 3 illustrates a first example where each wire 3 is insulated and where the insulation 11 remains intact except where the substrate surface 9 is polished to expose the wires. This will typically be the case when the substrate top part comprises a polymer that does not require a high temperature to be cured.

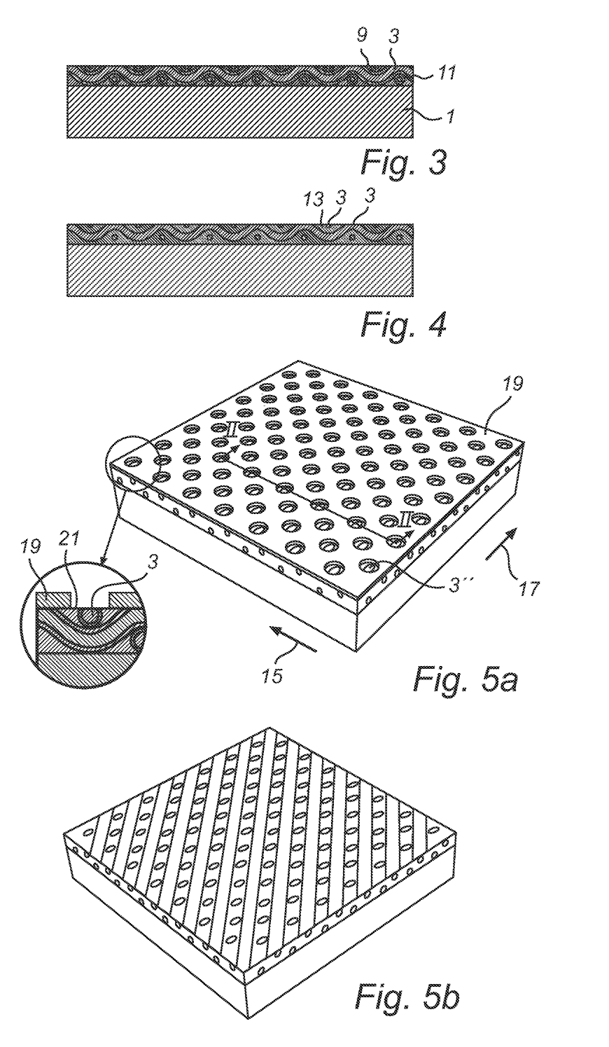

In the case of a glass substrate top part the situation in FIG. 4 may instead be realized. Then, the plastic wire insulation, due to the relatively higher process temperature, is gasified at least to some extent. However, during the process, the polymer material is replaced by the insulating glass particles, such that the wires remain insulated from each other, a gap 13 is kept between crossing conductors 3. To some extent the plastic insulation may also remain also in this case.

Next, the production of an OLED device is described, where both the cathode and the anode are connected to wires in the substrate. Such a device may be used for lighting and display purposes but also as a solar cell.

A polished substrate, similar to the one illustrated in FIG. 1d is used, but where the wires are mutually insulated where they cross. The woven structure is a bi-axial one where wires run in two directions 15, 17 (warp and weft), at substantially right angles. On this substrate an ITO layer 19 is applied with a conventional sputtering technique. By etching, the ITO layer 19 is made to cover the locations where the wires (warp) running in one direction 15 adjoin the surface, while leaving the locations where the wires 3″ running in the other direction 17 (weft) adjoin the surface open together with a small surrounding area 21, as illustrated in FIG. 5a.

FIG. 5b illustrates an alternative way to apply an anode layer. In this case the ITO layer is applied as a number of strips, which may be directed at 45° angle with the warp an weft directions and are place on top of the locations where wires in either the warp or weft adjoins the substrate surface. Thus the strips cover every second diagonal row of wire contact surfaces.

FIG. 6 illustrates a cross-section II-II through the device in FIG. 5a. As is clearly visible, the wires in the warp 3′ now electrically contacts the ITO layer 19 at several locations.

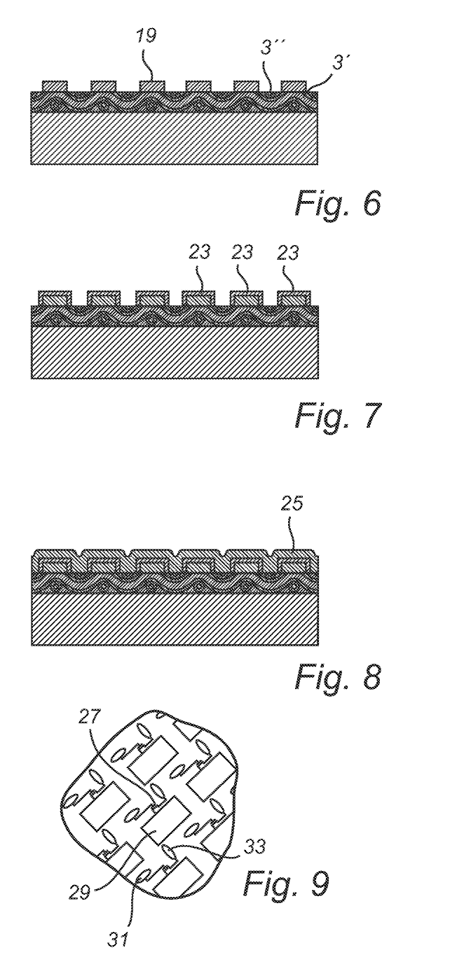

Now an organic layer 23 is applied on top of the ITO layer and extending somewhat into the free area around the locations where the weft wires adjoins the surface, as illustrated in FIG. 7. The organic layer is applied using a shadow mask in order to reproduce the organic layers at the right locations.

In a further step the cathode layer 25 which may consist of aluminum together with a Ba or LiF sublayer is applied over the entire surface using an evaporation technique. The cathode layer extends down to the areas where the weft wires adjoin the substrate surface, such that the cathode is allowed to be electrically connected to these wires. Note that the drawing in FIG. 7 is schematic for description purposes. In a typical embodiment the ITO layer may be 100 nm thick, the intermediate organic layer may be 100-200 nm thick, and the cathode 100 nm. As mentioned, the distance between two adjacent wires may be 10 mm, which is why a schematic drawing must be used to describe the structure.

In this device, both the anode and cathode layers will be shunted, such that the anode and cathode voltage may be substantially uniform over the entire surface.

If a substrate with a first electrode layer applied as in FIG. 5b is used, the organic material is instead applied on the stripes.

On the other hand, by applying different voltages to different wires in the warp and weft respectively, different areas of the OLED device may also be controlled to output different brightness levels. This however usually requires that the anode and/or cathode layers are divided into a plurality of mutually insulated segments.

The substrate illustrated in FIG. 3 may also be used e.g. in a TFT (Thin Film Transistor) LCD device where the wires are used to address different pixel in an active matrix scheme. FIG. 9 illustrates schematically how this can be carried out. The gates of the TFTs 27 may then be connected to wires 31 running in a first direction in the substrate, while the sources are connected to wires 33 running in the other direction. The TFT drains are each connected to an ITO electrode 29, which controls the polarizing effect of liquid crystals (not shown) situated on top of the ITO electrode, as is well known per se. The electrode layer is thus connected to the wires in the substrate via a transistor. The substrate may, as the skilled person realizes, be used in modified conventional TFT production processes. The advantage with the substrate in this context is that row and column lines need not be provided on top of the substrate, which simplifies the production. As in a conventional TFT LCD panel, a line of pixels or sub-pixels is updated by setting the corresponding gate wire high and applying image information signals at the source wires of the respective pixels/sub-pixels.

An inorganic LED display can be addressed in a similar way even without TFTs.

Thus the substrate described above may be used e.g. in different electro-optic devices comprising plural electrode layers.

OLEDs have already been mentioned. The disclosed substrate structure is applicable to types used for illumination or display purposes. In OLEDs for illumination, uniform light emission is achieved, and in display types the wires provide simple and reliable addressing. Solar cell and image sensor applications are also possible. As mentioned, the structure is also useful in TFT LCD devices.

In summary, the invention relates to a planar electro-optic device and a method for producing the same. The device comprises an embedded woven structure of conductive wires, which adjoin the top surface of the substrate at locations thereof. Different electrode layers may be connected to the wires at these locations. The wires may then be used e.g. to provide a uniform potential over an entire electrode surface, even if the electrode itself is very thin. A substrate of this kind may also be used for addressing purposes.

The invention is not restricted to the described embodiments. It can be altered in different ways within the scope of the appended claims.

1. An electro-optic device, having a planar substrate (7), and at least one electrode layer (19, 25; 29) and an active layer (23), on a first surface of the substrate, wherein
the substrate comprises a plurality of conductive wires (3, 3′, 3″), which are embedded in the substrate (7) and are arranged in a structure, such that the wires meander to and from said first substrate surface, and adjoins this surface at a number of locations thereof, and
said at least one electrode layer is connected to a plurality of said wires at a plurality of said locations.

2. An electro-optic device according to claim 1, wherein the wires are arranged in a woven structure.

3. An electro-optic device according to claim 2, wherein wires, crossing each other in the woven structure, are electrically insulated from each other.

4. An electro-optic device according to claim 3, wherein a first set of wires, running in a first direction in the woven structure, are connected to a first electrode layer, and a second set of wires, running in a second direction in the woven structure, are connected to a second electrode layer through apertures in the first electrode layer.

5. An electro-optic device according to claim 4, wherein the wires in at least one of said first or second set of wires are interconnected to remain on the same electrical potential.

6. An electro-optic device according to claim 3, wherein sub-sets of wires in at least one of said first or second set of wires are arranged to be controlled separately.

7. An electro-optic device according to claim 1, wherein at least one of said first or said second electrode layers is divided into mutually insulated sub-sections and wherein different sub-sections are connected to different wires in the structure.

8. An electro-optic device according to claim 1, wherein the substrate is flexible,

9. An electro-optic device according to claim 1, wherein the electro-optical device is a lighting device.

10. An electro-optic device according to claim 1, wherein the electro-optical device is a solar cell.

11. An electro-optic device according to claim 1, wherein the electro-optical device is an OLED display.

12. An electro-optic device according to claim 1, wherein the electro-optical device is a TFT display.

13. An electro-optic device according to claim 1, wherein the electro-optical device is an image sensor.

14. A method for producing an electro-optic device, the method comprising
arranging a plurality of conductive wires (3) in a structure on a planar base substrate part (1),
forming a top substrate layer (5) on top of the base substrate part, such that the structure is embedded in a substrate (7) formed by the base substrate part and the top substrate part,
removing an upper portion of the top substrate layer, such that parts of the conductive wires in the structure become exposed at locations in the substrate surface, and
applying at least one electrode layer (19, 25; 29) and an active layer (23) on the substrate, such that said at least one electrode layer is connected to a plurality of said wires at a plurality of said locations.

15. A method according to claim 14, wherein the wires are arranged in a woven structure.

16. A planar substrate for electro-optical devices, comprising a plurality of conductive wires (3) which are embedded in the substrate (7) and are arranged in a structure, such that the wires meander to and from a first substrate surface, and adjoins this surface at a number of locations thereof.

17. A planar substrate according to claim 16, wherein the wires are arranged in a woven structure.
